(19) United States
(12) Patent Application Publication
(10) Pub. No.: US 2012/0081102 A1
(43) Pub. Date: Apr. 5, 2012

(54) AUDIO JACK WITH GROUND DETECT

(75) Inventors: Zheng Gao, San Jose, CA (US); Nathan Johanningsmier, Cupertino, CA (US); Casey Hardy, Cupertino, CA (US); Eric Monsef, Los Gatos, CA (US); Chiachi Wu, Taipei (TW)

(73) Assignee: Apple Inc., Cupertino, CA (US)

(21) Appl. No.: 12/894,587

(22) Filed: Sep. 30, 2010

(51) Int. Cl. G01R 19/00

(52) U.S. Cl. 324/76.11

(57) ABSTRACT

Circuits, methods, and apparatus that provide an audio receptacle that can detect the presence of an audio jack without using mechanical switches or other such mechanical mechanisms. One example provides an audio receptacle having two contacts that may be electrically connected when an audio jack is inserted. When no audio jack is inserted into the audio receptacle, the two ground contacts may not be connected. When an audio jack is inserted into the audio receptacle, the resulting closed circuit may be detected and used to activate or otherwise turn on one or more audio circuits in or associated with the audio receptacle. Conversely, when no audio jack is inserted, the resulting open circuit may be detected and used to deactivate or otherwise turn off or reduce power in one or more audio circuits in or associated with the audio receptacle.

### BACKGROUND

Portable electronic devices, such as portable media players, tablet, netbook, and laptop computers, cell, media, and smart phones, have become ubiquitous in recent years. These devices often include an audio receptacle through which they receive and provide audio information. These audio receptacles may be arranged to receive an audio jack that may be connected to headphones, speakers, microphones, or other equipment.

The audio receptacles may include, or be connected to, electronic circuits such as audio drivers for driving headphones or speakers, audio receivers for receiving audio signals from a microphone, and others. But these circuits consume power, which is particularly undesirable in a portable electronic device. Thus, it may be desirable to turn off these circuits when they are not used, that is, when an audio jack is not inserted in the audio receptacle. Conversely, when an audio jack is inserted, it may be desirable to activate these circuits.

Conventional audio receptacles may employ one or more switches to detect the presence of an audio jack. These switches may be at least partly mechanical. For example, they may close when an audio jack is inserted in the audio receptacle. The closed switch may form a low impedance path that may be detected by a detection circuit in the audio receptacle. This detection may be used to activate one or more audio circuits in or associated with the audio receptacle.

Unfortunately, particulate matter or other debris may enter the audio receptacle. This particulate matter or debris may become lodged in one or more of these switches. With this particulate matter lodged in this way, a switch may be forced open, and may not close when an audio jack is inserted. This may keep the audio circuits deactivated, even when an audio jack is inserted into the audio receptacle.

Thus, what is needed are circuits, methods, and apparatus that provide an audio receptacle that can detect the presence of an audio jack without using mechanical switches or other such mechanical mechanisms that may become fouled with particulate matter or other debris and thus be rendered nonfunctional.

### SUMMARY

Accordingly, embodiments of the present invention provide circuits, methods, and apparatus that provide an audio receptacle that can detect the presence of an audio jack without using mechanical switches or other such mechanical mechanisms.

An illustrative embodiment of the present invention provides an audio receptacle having multiple contacts that may be electrically connected when an audio jack is inserted. A specific embodiment of the present invention may provide an audio receptacle that utilizes two ground contacts. When no audio jack is inserted into the audio receptacle, the two ground contacts may not be connected. This open circuit may be detected and used to deactivate or otherwise turn off or reduce power in one or more audio circuits in or associated with the audio receptacle. Conversely, when an audio jack is inserted into the audio receptacle, the two ground contacts may be connected. This closed circuit may be detected and used to activate or otherwise turn on one or more audio circuits in or associated with the audio receptacle.

Various embodiments of the present invention may detect a closed or open circuit between the two contacts in the audio receptacle in various ways. A specific embodiment of the present invention utilizes a resistor in series with a power supply or bias line. One end of the resistor is coupled to the power supply or bias line, while the other is connected to a first contact of the two contacts. A second contact of the two contacts may be connected to ground. In this way, when an audio jack is inserted into the audio receptacle, the first contact is grounded. This contact may also be connected to the input of a logic gate, such as an inverter. With the input of the inverter grounded, the inverter may provide a logic high signal that may be used as a power-on control line. Conversely, when there is no audio jack inserted in the audio receptacle, the first contact floats to the power supply or bias voltage. With the input of the inverter high, the output of the invert may provide a logic low signal that may be used to turn off power to one or more audio circuits.

An illustrative embodiment of the present invention may provide two contacts for ground, left, right, or microphone connections on an audio jack. A specific embodiment of the present invention provides two contacts for ground in order to reduce noise on the audio signals.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a portable media player having an audio receptacle that may be improved by the incorporation of an embodiment of the present invention;

FIG. 2 illustrates portions of an audio receptacle consistent with an embodiment of the present invention;

FIG. 3 illustrates a flowchart of a method of operating an audio receptacle according to an embodiment of the present invention; and

FIG. 4 illustrates a detection circuit according to embodiment of the present invention.

### DESCRIPTION OF ILLUSTRATIVE EMBODIMENTS

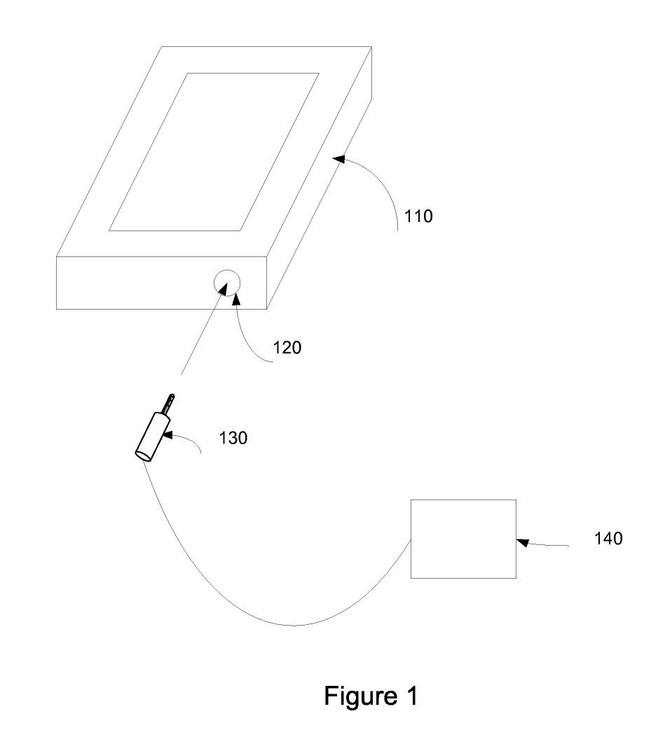

FIG. 1 illustrates a portable media player having an audio receptacle that may be improved by the incorporation of an embodiment of the present invention. Portable media player 110 may include audio receptacle 120. Audio receptacle 120 may be arranged to accept audio jack 130. That is, audio jack 130 may be inserted into audio receptacle 120. Audio jack 130 may further connect to electronic component 140. Electronic component 140 may include headphones, speakers, a microphone, a headset, or other electronic component.

While in this example portable media player 110 is shown to include audio receptacle 120, other embodiments of the present invention may provide audio receptacles for other types of devices, such as desktop, tablet, laptop, or netbook computers, cell, media, or smart phones, or other types of electronic devices. Also, while embodiments of the present invention are particularly suited for an audio receptacle, other embodiments of the present invention may be used to improve other types of receptacles.

Again, embodiments of the present invention may provide audio receptacles that avoid using mechanical switches that may become disabled or nonfunctional due to contamination from particulate matter or debris. An example is shown in the following figure.

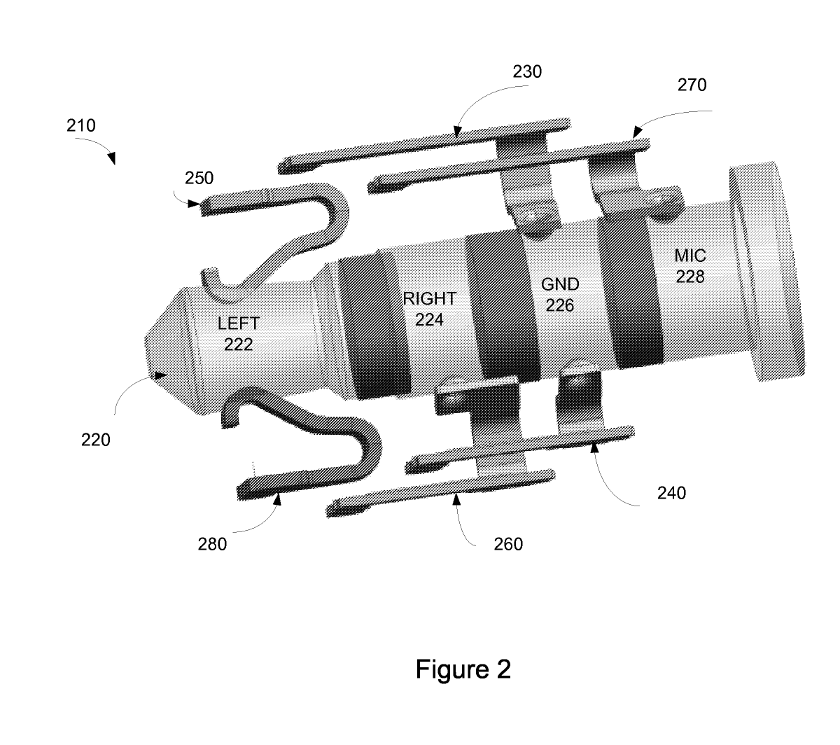

FIG. 2 illustrates portions of an audio receptacle consistent with an embodiment of the present invention. This figure, as with the other included figures, is shown for illustrative purposes and does not limit either the possible embodiments of the present invention or the claims.

Audio receptacle 210 is shown as accepting audio jack 220. That is, audio jack 220 is shown as being inserted into audio receptacle 210. Audio jack 220 is shown as a conventional audio jack, though in other embodiments of the present invention, jack 220 may be a nonstandard audio jack or other type of jack or connector insert. In this example, audio jack 220 includes contacts for left channel 222, right channel 224, ground 226, and microphone 228. Audio receptacle 210 may include left channel contact 250, right channel contact 260, ground contacts 230 and 240, and microphone contact 270. Audio receptacle 210 may also include an additional retaining clip 280.

These receptacle contacts and clip may provide a spring tension when audio jack 220 is inserted into audio receptacle 210 in order to improve electrical contact between contacts in audio receptacle 210 and contacts on audio jacks 220. The receptacle contacts may be formed using stainless steel, aluminum, copper, or other conductive material. Retaining clip 280 may be formed using stainless steel, aluminum, copper, plastic, or other conductive or nonconductive material. The audio receptacle contacts and retaining clip 280 may be housed in a receptacle housing formed of plastic or other nonconductive material. Audio receptacle 210 may include or be associated with one or more audio, power, or other types of circuits.

When audio jack 220 is inserted into audio receptacle 210, ground contact 226 on audio jack 220 electrically connects ground contacts 230 and 240 in audio receptacle 210 to each other. When this electrical connection is detected, circuitry in or associated with the audio receptacle 210 may determine that audio jack 220 is inserted into audio receptacle 210. Accordingly, various audio circuits (not shown) in, or associated with, audio receptacle 210 may be activated. When audio jack 220 is removed, in order to save power, a resulting disconnect between ground contacts 230 and 240 may be detected and used to shut off one or more audio circuits in, or associated with, audio receptacle 210.

In this example, the presence or absence of audio jack 220 may be determined without the use of a mechanical switch. In this way, there is no switch to get blocked by particulate matter other debris. Also in this example, if a piece of debris does block an electrical connection, for example an electrical connection between a ground contact 230 or 240 of the audio receptacle and ground 226 on the audio jack, it is likely a user would instinctively remove and reinsert audio jack 220, thereby likely dislodging the offending object.

In this particular example, audio receptacle 210 may include two ground contacts 230 and 240. In other embodiments of the present invention, two left, right, or microphone contacts may be included.

Various embodiments of the present invention may employ two ground contacts instead of two contacts on the left, right, or microphone channels. This prevents leakage current generated by detection circuitry from affecting the audio quality on these channels. For example, two ground contacts 230 and 240 may be used such that any noise resulting from a detection of a connection between ground contacts 230 and 240 are shunted to ground and do not generate noise on an audio channel. Specifically, one of ground contacts 230 and 240 may be connected to ground. This ground connection may have a low impedance, such that any current flowing between ground contacts 230 and 240 is passed to ground through a low-impedance path.

When audio jack 220 is inserted, ground contacts 230 and 240 may initially encounter left channel 222 on audio jack 220. This may electrically connect contacts 230 and 240 in audio receptacle 210, which may in turn trigger detection circuitry that may indicate that audio jack 220 has been inserted into audio receptacle 210. Similarly, contacts 230 and 240 may be electrically connected by right audio jack contact 224 as audio jack 220 is inserted. Accordingly, embodiments of the present invention may employ a delay mechanism, wherein the detection of an electrical connection between contacts 230 and 240 may be delayed. In this way, the detection circuitry may ignore the electrical connections of contacts 230 and 240 by the left 222 and right 224 audio jack contacts as audio jack 220 is inserted into audio receptacle 210.

Again, in this example, it may be determined whether an electrical connection between two or more contacts exists. Based on this determination, audio circuits may be activated or deactivated. An example is shown in the following figure.

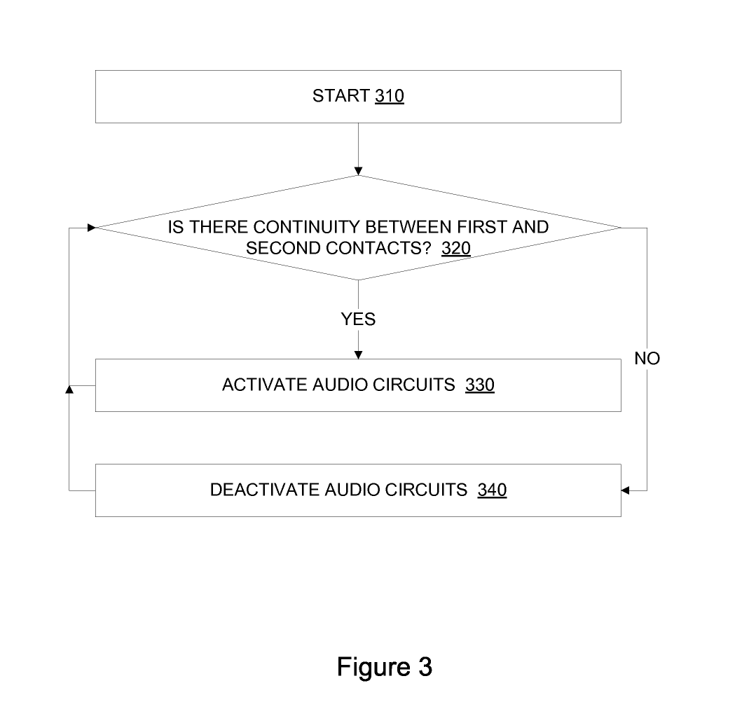

FIG. 3 illustrates a flowchart of a method of operating an audio receptacle according to an embodiment of the present invention. In act 310, the operation of an audio receptacle according to an embodiment of the present invention may begin. In act 320, it may be determined whether there is continuity between a first and second contact. That is, it may be determined whether the first contact and the second contact are connected together. If they are connected together, it is known that an audio jack is inserted, and one or more audio circuits in, or associated with, the audio receptacle may be activated in act 330. If there is no continuity between the first and second contacts, it is known that an audio jack is not inserted in the audio receptacle, and one or more audio circuits in, or associated with, the audio receptacle may be deactivated or placed in a lower-power state.

Various embodiment of the present invention may employ various techniques to determine whether such continuity exists between a first contact in the second contact. One example is shown in the following figure.

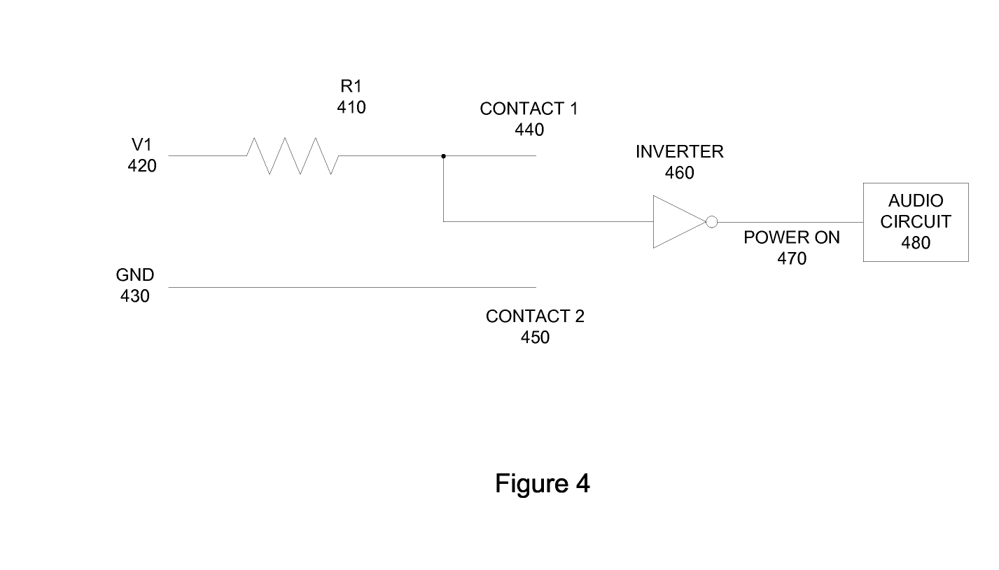

FIG. 4 illustrates a detection circuit according to embodiment of the present invention. In this example, resistor R1 410 may be placed between voltage supply or bias line 420 and first contact 440. Second contact 450 may be grounded, that is, it may be connected to ground connection 430. When first contact 440 and second contact 450 are connected or shorted together through a contact on an audio jack, the resulting voltage on first contact 440 is ground. This low-logic level may be received by inverter 460, which may provide a high logic level for power-on signal 470 that may received by audio circuit 480. This high power-on signal on line 470 may be used to activate circuitry in audio circuit 480. Conversely, when first contact 440 and second contact 450 are not connected, the resulting voltage on first contact 440 may be approximately equal to voltage V1 on line 420. This high-logic level may be received by inverter 460, which may provide a low-logic level for the power-on signal on line 470 that may be received by audio circuit 480. This low-logic level signal may be used to power off or deactivated some or all of audio circuit 480. Power-on signal 470 (or other related signal) may be delayed to delay the power-up of audio circuit 480 as an audio jack is inserted into an audio receptacle. This may prevent audio circuitry 480 from powering up when left or right channels on an audio jack electrically connect first contact 440 and second contact 450. This, in turn, may prevent audio artifacts from being generated as an audio jack is inserted into an audio receptacle.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. An audio receptacle comprising:
a first contact to mate with a contact on an audio jack;
a second contact to mate with the contact on the audio jack, the second contact separate from the first contact;
a detect circuit for detecting whether the first contact is electrically connected to the second contact; and
an audio circuit coupled to the detect circuit.

2. The audio receptacle of claim 1 wherein the first and second contacts are ground contacts.

3. The audio receptacle of claim 1 wherein the first contact and the second contact are electrically connected when an audio jack is inserted into the audio receptacle.

4. The audio receptacle of claim 1 wherein the first and second contacts are ground contacts and the audio receptacle further comprises:
a third contact for a left audio channel; and
a fourth contact for a right audio channel.

5. The audio receptacle of claim 4 wherein the third contact acts as a part of a retaining clip.

6. The audio receptacle of claim 5 wherein the third contact and a first clip portion act as the retaining clip.

7. The audio receptacle of claim 1 wherein the second contact is coupled to a ground in an electronic device, the electronic device housing the audio receptacle.

8. The audio receptacle of claim 7 wherein the detect circuit detects whether the first contact is electrically connected to ground.

9. The audio receptacle of claim 8 wherein the detect circuit further comprises a delay circuit to delay a signal indicating whether the first contact is electrically connected to ground.

10. The audio receptacle of claim 8 wherein the audio circuit operates at a higher power level when the detect circuit detects that the first contact is electrically connected to ground.

11. The audio receptacle of claim 1 wherein the audio circuit operates at a higher power level when the detect circuit detects that the first contact is electrically connected to the second contact.

12. An electronic device comprising:
an audio receptacle to receive an audio jack, the audio receptacle comprising:
a first ground contact to form an electrical connection with a contact on the audio jack; and
a second ground contact to form an electrical connection with the contact on the audio jack; and
an audio circuit, wherein the audio circuit operates at a higher power level when the first ground contact is electrically connected to the second ground contact and the audio circuit operates at a lower power level when the first ground contact is not electrically connected to the second ground contact.

13. The electronic device of claim 12 wherein the first ground contact and the second ground contact are electrically connected when an audio jack is inserted into the audio receptacle.

14. The electronic device of claim 12 wherein the audio receptacle further comprises:
a third contact for a left audio channel; and
a fourth contact for a right audio channel.

15. The electronic device of claim 14 wherein the audio receptacle further comprises:
a fifth contact for a microphone.

16. The electronic device of claim 12 wherein the second contact is coupled to a ground in the electronic device.

17. The electronic device of claim 16 further comprising a detect circuit, wherein the detect circuit detects whether the first ground contact is electrically connected to ground.

18. The electronic device of claim 16 wherein the detect circuit further comprises a delay circuit to delay a signal indicating whether the first ground contact is electrically connected to ground.

19. The electronic device of claim 16 wherein the audio circuit operates at a higher power level when the detect circuit detects that the first contact is electrically connected to ground.

20. A method of operating a audio receptacle comprising:
detecting whether a first contact is electrically connected to a second contact through a contact on an audio jack; and
if the first contact is not electrically connected to the second contact, then deactivating a first audio circuit; otherwise
if the first contact is electrically connected to the second contact, then activating the first audio circuit.

21. The method of claim 20 wherein detecting whether the first contact is electrically connected to the second contact comprises sensing a voltage on the first contact.

22. The method of claim 20 wherein the second contact is connected to ground, and detecting whether the first contact is electrically connected to the second contact comprises sensing whether the first contact is connected to ground.

23. The method of claim 20 further comprising delaying the detecting whether the first contact is electrically connected to the second contact.

24. The method of claim 20 wherein deactivating a first audio circuit comprises deactivating an audio output circuit.

25. The method of claim 20 wherein deactivating a first audio circuit comprises deactivating microphone input circuit.
